(19) United States
(12) Patent Application Publication
(10) Pub. No.: US 2007/0248767 A1
(43) Pub. Date: Oct. 25, 2007

(54) METHOD OF SELF-CLEANING OF CARBON-BASED FILM

(75) Inventors: Seiji Okura, Tokyo (JP); Yukihiro Mori, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/697,393

(22) Filed: Apr. 6, 2007

Related U.S. Application Data
(60) Provisional application No. 60/745,102, filed on Apr. 19, 2006.

(51) Int. Cl. D01F 9/12; B08B 6/00; B08B 9/00; C23C 16/00; C23C 14/02; H05H 1/00

(52) U.S. Cl. 427/534; 423/447.3; 134/1.1; 134/22.1; 427/249.1; 427/535

(57) ABSTRACT

A method of self-cleaning a plasma reactor upon depositing a carbon-based film on a substrate a pre-selected number of times, includes: (i) exciting oxygen gas and/or nitrogen oxide gas to generate a plasma; and (ii) exposing to the plasma a carbon-based film accumulated on an upper electrode provided in the reactor and a carbon-based film accumulated on an inner wall of the reactor.

### CROSS-REFERENCE TO RELATED APPLICATIONS

This application claims the benefit of U.S. Provisional Application No. 60/745,102, filed Apr. 19, 2006, the disclosure of which is herein incorporated by reference in its entirety.

### BACKGROUND OF THE INVENTION

1. Field of the Invention

The present invention relates to a method of self-cleaning of a carbon-based film deposited inside a reactor.

2. Description of the Related Art

In semiconductor processing techniques, optical films such as antireflective films and hard masks are used. In conventional techniques, these films are formed mainly by a technique called a coating method. The coating method forms highly functional polymer films by coating a liquid material and sintering it. It is, however, difficult to form a thin film on a substrate because a liquid having viscosity is coated. As semiconductor chip sizes continue to shrink, more thinned and higher-strength films are required.

As an advantageous method for achieving thinner films, use of a DLC (diamond-like carbon) film or an amorphous carbon film by plasma CVD has been reported (e.g., U.S. Pat. No. 5,470,661, U.S. Pat. No. 6,428,894). In these cases, using a molecule which is gaseous at room temperature as a material, a diamond-like carbon film or an amorphous carbonous film is formed by decomposing the molecule by plasma. Using a plasma CVD method gives promise of facilitating to achieve thinner films.

U.S. patent application Ser. No. 11/172,031, filed Jun. 30, 2005, owned by the same assignee as in the present application (the disclosure of which is herein incorporated by reference in its entirety) discloses a carbon polymer film capable of having a wide variety of structures, which is widely and industrially useable as high-strength materials such as a hard mask and various highly-functional materials. The carbon polymer can be produced by plasma CVD from organic monomers having high molecular weight such as benzene and can actualize a wide variety of structures and characteristics.

In a single-substrate- or small-batch substrate-processing apparatus, during CVD processing, a film is formed not only on a substrate but also on inner walls or other inner parts of a CVD chamber. The unwanted film on the inner parts of the chamber produces particles which deposit on a substrate during CVD processing and deteriorate the quality of a film on the substrate. Thus, the CVD chamber is cleaned periodically by using an in-situ cleaning process to remove unwanted adhesive products from an inner surface of the CVD chamber. Accumulation of unwanted adhesive products on surfaces of electrodes may affect plasma generation or distribution over a substrate and may cause damage to the electrodes. Further, unwanted adhesive products may cause generation of contaminant particles.

When pure or fluorine-doped SiO2 and SiN are deposited in a CVD reactor, sediment on inner surfaces of the CVD reactor can be removed by remote plasma cleaning. To reduce green house effect, NF₃ gas is generally applied with remote plasma technology. In that case, Argon gas is added as a feedstock to stabilize plasma discharge in a remote plasma chamber isolated from the CVD reactor. This technology is disclosed in U.S. Pat. No. 6,187,691, and U.S. Patent Publication No. 2002/0011210A. The following references also disclose chamber cleaning technologies. U.S. Pat. No. 6,374,831, U.S. Pat. No. 6,387,207, U.S. Pat. No. 6,329,297, U.S. Pat. No. 6,271,148, U.S. Pat. No. 6,347,636, U.S. Pat. No. 6,187,691, U.S. Patent Publication No. 2002/0011210A, U.S. Pat. No. 6,352,945, and U.S. Pat. No. 6,383,955. The disclosure of the foregoing references is herein incorporated by reference in their entirety, especially with respect to configurations of a reactor and a remote plasma reactor, and general cleaning conditions.

However, the above conventional methods are not effective in cleaning a carbon-based film such as the amorphous carbon film including diamond-like carbon film and the carbon polymer film described above, which have high carbon contents.

### SUMMARY OF THE INVENTION

In an aspect, the present invention provides a method of continuously forming carbon-based films on substrate, comprising: (i) forming a carbon-based film on a substrate in a reactor a pre-selected number of times; (ii) exciting oxygen gas and/or nitrogen oxide gas to generate a plasma for cleaning; (iii) cleaning an inside of the reactor with the plasma to remove particles accumulated during step (i) on the inside of the reactor; and (iv) repeating steps (i)-(iii) a pre-selected number of times.

The above aspect includes, but is not limited to, the following embodiments:

Step (ii) may be conducted in the reactor or may be conducted in the reactor and in a remote plasma unit. The method may further comprise determining a priority area of cleaning inside the reactor prior to step (ii). Step (iii) may comprise controlling pressure inside the reactor according to the priority area of cleaning.

Step (iii) may comprise controlling pressure inside the reactor at about 100 Pa to about 400 Pa when the priority area of cleaning is an inner wall of the reactor. Step (iii) may comprise controlling pressure inside the reactor at about 400 Pa to about 800 Pa when the priority area of cleaning is an upper electrode.

The method may further comprise selecting a cleaning gas including the oxygen gas and/or nitrogen oxide gas prior to step (ii) according to the priority area of cleaning. Step (iii) may comprise a step for adjusting a ratio of a cleaning rate at an inner wall of the reactor to a cleaning rate at an upper electrode to 3/100 to 110/100 according to the priority area of cleaning.

Step (iii) may comprise controlling a gap between an upper electrode and a lower electrode according to the priority area of cleaning. Step (ii) may further comprise exciting a fluorine-containing gas, a flow rate of which is lower than that of the oxygen gas and/or nitrogen oxide gas, when the priority area of cleaning is an inner wall. Step (ii) may further comprise exciting an inert gas, N₂ gas, and/or CO₂ gas, a total flow rate of which is lower than that of the oxygen gas and/or nitrogen oxide gas, when the priority area of cleaning is an inner wall. Step (ii) may comprise exciting predominantly the nitrogen oxide gas when the priority area of cleaning is an inner wall. Step (ii) may comprise exciting predominantly the oxygen gas without a fluorine-containing gas when the priority area of cleaning is an upper electrode.

In the above, the oxygen gas and/or nitrogen oxide gas may be O₂ gas and/or N₂O gas.

The carbon-based polymer film in step (i) may be a carbon polymer film formed by: (a) vaporizing a hydrocarbon-containing liquid monomer (C_{α}H_{β}X_{γ}, wherein α and are natural numbers of 5 or more; γ is an integer including zero; X is O, N or F) having a boiling point of about 20° C. to about 350° C. which is not substituted by a vinyl group or an acetylene group; (b) introducing said vaporized gas into a CVD reaction chamber inside which a substrate is placed; and (c) forming a hydrocarbon-containing polymer film on said substrate by plasma polymerization of said gas.

In another aspect, the present invention provides a method of self-cleaning a plasma reactor using a cleaning gas containing oxygen gas and/or nitrogen oxide gas at a pre-selected pressure upon depositing a carbon-based film on a substrate a pre-selected number of times, comprising: (i) changing the cleaning gas and/or the pressure; the step of changing the cleaning gas comprising (a) increasing a flow rate of oxygen gas for increasing a ratio of an etching rate of a carbon polymer accumulated on an upper electrode provided in the reactor to an etching rate of a carbon polymer accumulated on an inner wall of the reactor, or (b) increasing a flow rate of nitrogen oxide gas and/or adding to the cleaning gas at least one gas selected from the group consisting of fluorine-containing gas, inert gas, N₂ gas, and CO₂ gas for decreasing a ratio of an etching rate of the carbon polymer on the upper electrode to an etching rate of the carbon polymer on the inner wall; the step of changing the pressure comprising (c) increasing the pressure for increasing a ratio of an etching rate of the carbon-based film on the upper electrode to an etching rate of the carbon-based film on the inner wall, or (d) decreasing the pressure for decreasing a ratio of an etching rate of the carbon-based film on the upper electrode to an etching rate of the carbon-based film on the inner wall; and (ii) conducting self-cleaning of the reactor using the changed cleaning gas and/or the changed pressure.

In still another aspect, the present invention provides a method of self-cleaning a plasma reactor upon depositing a carbon-based film on a substrate a pre-selected number of times, comprising: (i) exciting oxygen gas and/or nitrogen oxide gas to generate a plasma; and (ii) exposing to the plasma a carbon-based film accumulated on an upper electrode provided in the reactor and a carbon-based film accumulated on an inner wall of the reactor.

The above aspect includes, but is not limited to, the following embodiments:

In step (i), the plasma may be generated only from oxygen gas. In step (i), the plasma may be generated only from nitrogen oxide gas. The oxygen gas may be O₂ gas, and the nitrogen oxide gas may be N₂O gas.

In all of the aforesaid aspects and embodiments, any element used in an aspect or embodiment can interchangeably or additionally be used in another aspect or embodiment unless such a replacement is not feasible or causes adverse effect.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic view showing an example of a CVD apparatus which can be used in an embodiment of the present invention.

FIG. 2 is a graph showing the relationship between the number of particles and the number of substrates processed, wherein two types of cleaning were conducted according to embodiments of the present invention.

### DETAILED DESCRIPTION OF THE PREFERRED EMBODIMENT

The present invention is described in detail using preferred embodiments. The present invention, however, is not limited to these embodiments. Additionally, a requirement in an embodiment is freely applicable to other embodiments, and requirements are mutually replaceable unless special conditions are attached.

The self-cleaning method of the present invention can be applied to a reactor upon depositing a film on a substrate a pre-selected number of times in the reactor. In an embodiment, the cleaning of the reactor can be conducted every after one substrate is processed. In another embodiment, the cleaning of the reactor can be conducted every after a given number of substrates (e.g., 2-50 substrates, typically 5-25 substrates) are processed. The frequency of cleaning can be determined depending on the amount of unwanted film accumulated inside the reactor during a deposition process, the amount of particles generated by the cleaning itself, etc.

The reactor may be a capacitively-coupled plasma apparatus wherein a showerhead which can serve as an upper electrode and a susceptor which serves as a lower electrode are disposed in parallel to each other. The reactor may be a PECVD apparatus, HDP-CVD apparatus, ALD apparatus, etc. in which unwanted particles are accumulated on the showerhead and the inner wall during deposition of film of interest on a substrate.

The film deposited on a substrate in the reactor, upon deposition of which the cleaning inside the reactor of the present invention is conducted, is a carbon-based film which may be defined as a film containing 30% or more carbon (typically 30% to 80%, preferably 40% to 60%) per mass of the entire compositions in an embodiment. In another embodiment, the carbon-based film may be defined as a film formed with a carbon skeleton. In another embodiment, the carbon-based film may be defined as a film having a general formula CxHy (x, y are an integer of 2 or greater). The carbon-based film includes, but is not limited to, a nano-carbon polymer film disclosed in U.S. patent application Ser. No. 11/172,031, filed Jun. 30, 2005, and No. 11/524,037, filed Sep. 20, 2006, both owned by the same assignee as in the present application (the disclosure of which is herein incorporated by reference in their entirety), and an amorphous carbon film (including diamond-like carbon film) disclosed in U.S. Patent Publications No. 2003/0091938 and No. 2005/0112509, U.S. Pat. No. 5,470,661, and U.S. Pat. No. 6,428,894 (the disclosure of which is herein incorporated by reference in their entirety).

For example, as disclosed in U.S. patent application Ser. No. 11/172,031 mentioned above, a nano-carbon polymer film can be formed a method which comprises the steps of vaporizing a hydrocarbon-containing liquid monomer (C_{α}H_{β}X_{γ}, wherein α and β are natural numbers of 5 or more; γ is an integer including zero; X is O or N) having a boiling point of 20° C.-350° C. which is not substituted by a vinyl group or an acetylene group, introducing the vaporized gas into a CVD reaction chamber inside which a substrate is placed, and forming a hydrocarbon-containing polymer film on the substrate by plasma polymerizing the gas. The substrate is, for example, a semiconductor device substrate. In the above method, the liquid monomer may be introduced into a heater disposed upstream of the reaction chamber and vaporized. Additionally, the liquid monomer may be flow-controlled by a valve upstream of the heater, and introduction of the liquid monomer into the heater may be blocked by a shutoff valve disposed between the flow control valve and the heater and kept at 80° C. or lower or at a temperature lower than that of heating/vaporization by approximately 50° C. or more except when a film is formed. Or, the liquid monomer may be flow-controlled by a valve disposed upstream of the heater and kept at 80° C. or lower or at a temperature lower than that of heating/vaporization by approximately 50° C. or more, and at the same time introduction of the liquid monomer into the heater may be blocked except when a film is formed.

Further, as disclosed in U.S. patent application Ser. No. 11/172,031, usable liquid organic monomers for a nano-carbon polymer film are as follows:

As a liquid organic monomer, cyclic hydrocarbon can be used. The cyclic hydrocarbon may be substituted or non-substituted benzene. Further, the substituted or non-substituted benzene may be C₆H₆₋ₙRₙ (wherein n, 0, 1, 2, 3); R may be independently —CH₃ or —C₂H₅. The liquid monomer may be a combination of two types or more of substituted or non-substituted benzene. In the above, the substituted benzene may be any one or more of 1,3,5-trimethylbenzene, o-xylene, m-xylene or p-xylene; in addition to a benzene derivative, the cyclic hydrocarbon may be any one or more of cyclohexane, cyclohexene, cyclohexadiene, cyclooctatetraene, cyclopentane, and cyclopentene. The liquid monomer may be linear hydrocarbon, and the linear hydrocarbon may also be any one or more of pentane, iso-pentane, neo-pentane, hexane, 1-pentene, 1-hexene, 1-pentyne, and isoprene.

As a specific example, C₆H₃(CH₃)₃ (1,3,5-trimethylbenzene (TMB); boiling point of 165° C.) or C₆H₄(CH₃)₂ (dimethylbenzene (xylene); boiling point of 144° C.) can be mentioned. In addition to the above, as liner alkane (CₙH₂(n+1)), pentane (boiling point of 36.1° C.), iso-pentane (boiling point of 27.9° C.) or neo-pentane (boiling point of 9.5° C.), wherein n is 5, or hexane (boiling point: 68.7° C.) or isoprene (boiling point: 34° C.), wherein n is 6, can be used singly or in any combination as a source gas.

Additionally, a liquid organic monomer is a hydrocarbon-containing liquid monomer (C_{α}H_{β}X_{γ}, wherein α and β are natural numbers of 5 or more; γ is an integer including zero; X is O, N or F) having a boiling point of room temperature or higher (e.g., approximately 20° C.-approximately 350° C.). Using this monomer, a hard mask is formed. Preferably, the carbon number is 6-30; the carbon number is 6-12. In this case as well, the liquid monomer is cyclic hydrocarbon, and the cyclic hydrocarbon may also be substituted or non-substituted benzene. Further, the substituted benzene or the non-substituted benzene may be C₆H₆₋Rₙ (wherein n is 0, 1, 2, or 3); R may be independently —CH₃, —C₂H₅, or —CH═CH₂. Additionally, the liquid monomer is a combination of two types or more of the non-substituted benzene.

In the above, the substituted benzene may be any one of 1,3,5-trimethylbenzene, o-xylene, m-xylene, or p-xylene; In addition to benzene derivatives, the cyclic hydrocarbon may be any one of cyclohexene, cyclohexadiene, cyclooctatetraene. Additionally, it may be linear hydrocarbon; the linear hydrocarbon may be pentane, iso-pentane, neo-pentane, hexane, 1-pentene, 1-hexene, 1-pentyne, and/or isoprene.

Additionally, a reaction gas composed of only the liquid monomer may be used. Specifically, C₆H₅(CH═CH₂) (vinylbenzene (styrene); boiling point of 145° C.) can be mentioned. In addition to this, as liner alkene (CₙHₙ (n=5)), 1-pentene (boiling point of 30.0° C.); or as liner alkyne (CₙH₂₍ₙ₋₁₎ (n=5), 1-pentyne (boiling point of 40.2° C.), etc. can be used singly or in any combination as a source gas.

In the present invention, the cleaning of the reactor can be in-situ plasma cleaning in an embodiment, remote plasma cleaning in another embodiment, or a combination of in-situ plasma cleaning and remote plasma cleaning in still another embodiment. General methods of in-situ plasma cleaning and remote plasma cleaning are disclosed in U.S. Pat. No. 6,187,691, U.S. Patent Publication No. 2002/0011210A, U.S. Pat. No. 6,374,831, U.S. Pat. No. 6,387,207, U.S. Pat. No. 6,329,297, U.S. Pat. No. 6,271,148, U.S. Pat. No. 6,347,636, U.S. Pat. No. 6,187,691, U.S. Patent Publication No. 2002/0011210A, U.S. Pat. No. 6,352,945, and U.S. Pat. No. 6,383,955, for example, the disclosure of which is herein incorporated by reference in their entirety.

During the process of depositing a carbon-based film on a substrate a pre-selected number of times, a carbon-based film is also deposited on areas other than the substrate such as an inner wall and a showerhead (an upper electrode). Upon completion of deposition of a carbon-based film on a substrate, the cleaning of the reactor is initiated. If a fluorine-containing gas such as NF₃, C₂F₆, or C₃F₈, is used as a cleaning gas, fluorine binds to hydrogen present in the carbon-based film during a cleaning process, thereby generating HF which is likely to cause erosion to a showerhead or susceptor made of aluminum or its alloy. Consequently, contaminant particles are generated and accumulate on an inner wall or the showerhead, and then fall on a substrate surface during a deposition process. Alternatively or additionally, if a fluorine-containing gas such as NF₃, C₂F₆, or C₃F₈, is used as a cleaning gas, fluorine binds to aluminum which is the main material of an upper electrode, thereby generating aluminum fluoride (AlF) which is likely to be a cause of particle contamination on a showerhead surface. The above theories are not intended to limit the present invention.

In an embodiment of the present invention, a carbon-based film can effectively be removed using oxygen gas and/or nitrogen oxide gas. When using oxygen gas and/or nitrogen oxide gas as a cleaning gas, C and H in the carbon-based film (e.g., C:H=50%:50%) react with 0 and generate CO₂ and H₂O which are discharged from the reactor to an exhaust system. These species are not likely to cause erosion to electrodes, thereby suppressing generation of contaminant particles.

When nitrogen oxide gas is added to oxygen gas, a plasma can be more stabilized and distributed widely inside the reactor, thereby more uniformly supplying an etchent (etching agent) to a wide area of the reactor. As a result, it is possible to increase a cleaning rate without causing damage to the electrodes. A ratio of oxygen gas to nitrogen oxide gas may be 100:0 to 0:100 including 90:10, 80:20, 70:30, 60:40, 50:50, 40:60, 30:70, 20:80, 10:90, and ranges between any two numerals of the foregoing. The ratio can be selected depending on a priority or target area of cleaning in the cleaning process. If priority is given to electrodes for cleaning, the ratio may be set high, and if priority is given to an inner wall of the reactor, the ratio may be set low. For example, if the deposition temperature is relatively low, accumulation of more particles on the electrodes and the inner wall of the reactor occurs, and if the deposition temperature is relatively high, accumulation of less particles occurs. It is possible to determine in advance through experiments which section of the reactor needs to be targeted more than other sections for cleaning.

In the above embodiments and embodiment described below, the oxygen gas may be O₂ gas or O₃ gas singly or in combination, and preferably O₂ gas. The nitrogen oxide gas may be N₂O gas, NO gas, N₂O₃ gas, or NO₂ gas singly or in any combination, and preferably N₂O gas.

In an embodiment, the cleaning steps includes changing a cleaning gas by (a) increasing a flow rate of oxygen gas for increasing a ratio of an etching rate of a carbon-based film accumulated on an upper electrode provided in the reactor to an etching rate of a carbon-based film polymer accumulated on an inner wall of the reactor, or (b) increasing a flow rate of nitrogen oxide gas for decreasing a ratio of an etching rate of the carbon-based film on the upper electrode to an etching rate of the carbon-based film on the inner wall. The flow rate of oxygen gas may be in the range of 100 sccm to 10,000 sccm, including 500 sccm, 1,000 sccm, 2,000 sccm, 3,000 sccm, 5,000 sccm, 7,000 sccm, and ranges between any two numbers of the foregoing, preferably more than 2,000 sccm and less than 7,000 sccm. The flow rate of nitrogen oxide gas may be in the range of 10 sccm to 6,000 sccm, including 50 sccm, 100 sccm, 500 sccm, 1,000 sccm, 2,000 sccm, 5,000 sccm, and ranges between any two numbers of the foregoing, preferably more than 1,000 sccm and less than 3,000 sccm. The total flow rate of a cleaning gas may be in the range of 100 sccm to 10,000 sccm, including 500 sccm, 1,000 sccm, 2,000 sccm, 3,000 sccm, 5,000 sccm, 7,000 sccm, and ranges between any two numbers of the foregoing, preferably more than 2,000 sccm and less than 7,000 sccm. The cleaning gas may contain oxygen gas and/or nitrogen oxide gas in an amount of more than 50% to 100% of the cleaning gas (including 60%, 70%, 80%, 90%, 95%, and ranges between any two numbers of the foregoing, preferably more than 90%).

In addition, in in-situ plasma cleaning, by controlling cleaning pressure, a cleaning rate (etching rate) can be adjusted differently between an electrode and an inner wall of the reaction. For example, at a high pressure such as about 800 Pa, a plasma tends to converge between the upper and lower electrodes, and thus, carbon-based film accumulated on the electrodes can effectively be removed. In the above, the etching rate at the electrodes can be increased, while the etching rate on the inner wall can be decrease (or is not as much increased as that at the electrodes) as compared with those at a low pressure such as about 100 Pa. On the other hand, at a low pressure such as about 100 Pa, a plasma tends to diverge and reach an inner wall of the reactor, and thus, carbon-based film accumulated on the inner wall can effectively be removed. In the above, the etching rate on the inner wall can be increased, while the etching rate at the electrode can be decreased (or is not as much increased as that on the inner wall) as compared with those at a high pressure such as about 800 Pa.

The pressure may be controlled at about 100 Pa to about 800 Pa in an embodiment. If the pressure is less than about 100 Pa, the etching rate tends to decrease and become insufficient. If the pressure is more than about 800 Pa, a plasma converges on the electrodes and tends to cause damage to the electrodes. For example, in order to increase the etching rate at the electrode, the pressure may be controlled at about 400 Pa to about 800 Pa. In order to increase the etching rate on the inner wall of the reactor, the pressure may be controlled at about 100 Pa to about 400 Pa.

In an embodiment, the steps of cleaning includes changing the pressure by (c) increasing the pressure for increasing a ratio of an etching rate of the carbon-based film on the upper electrode to an etching rate of the carbon-based film on the inner wall, or (d) decreasing the pressure for decreasing a ratio of an etching rate of the carbon-based film on the upper electrode to an etching rate of the carbon-based film on the inner wall.

Radio-frequency (RF) power for generating a plasma for cleaning can be of a conventional frequency such as 13.56 MHz or 27.12 MHz or can be of the conventional frequencies in combination with a low frequency such as 350 kHz or 430 kHz. A mixture of high-frequency RF power and low-frequency RF power can increase the overall etching rate in an embodiment. The ratio of high-frequency RF power to low-frequency RF power may be 100:5 to 100:60, preferably 100:10 to 100:30). In an embodiment, RF power is of 500 W to 3,000 W, preferably 1,000 W to 2,000 W. In another embodiment, RF power is of 1,000 W to 4,000 W, preferably 2,500 W to 3,000 W, especially in combination with a high oxygen flow such as 5,000 sccm to 10,000 sccm. This embodiment is suitable for a reaction chamber for a substrate having a diameter of 300 mm, for example.

In an embodiment, by adjusting a gap between the upper electrode and the lower electrode, a cleaning rate (etching rate) can be adjusted differently between an electrode and an inner wall of the reaction. For example, when the gap is small, the etching rate at the electrodes can be increased; and when the gap is large, the etching rate on the inner wall can be increased. In an embodiment, the gap between the upper and lower electrodes may be in the range of 10 mm to 100 mm including 20 mm, 30 mm, 50 mm, 70 mm, and ranges between any two numbers of the foregoing.

Temperature of the reactor (the temperature of a susceptor) may be 100-700° C., including 200, 300, 400, 500, 600° C., and any ranges between any two numbers of the foregoing.

In another embodiment, a cleaning gas may further comprise fluorine-containing gas such as one or more of F₂, NF₃, CF₄, C₂F₆, C₃F₈, C₄F₈, CHF₃, SF₆, and COF₂ in order to increase the etching rate and to expand an effective etching area. However, fluorine-containing gas may cause detaching of an anode oxide film formed on a surface of the upper electrode made of aluminum or its alloy and may cause erosion of the aluminum surface of the electrode, or such fluorine-containing gas may cause forming of aluminum-fluoride on a aluminum surface of upper electrode (in the case of a showerhead having no anodic oxide film), thereby generating contaminant particles. Fluorine-containing gas may be added in an amount of about 1% to about 10% (preferably less than 5% in an embodiment, 5-9% in another embodiment) of the total cleaning gas. The gas of high amount fluorine shows higher etching rate but it may intensively show the above contamination issue. Thus, the amount of fluorine-containing gas should be optimized considering the above.

The cleaning may be conducted every after processing a single substrate or more than one substrate. The frequency of cleaning may be reduced to every 5 to 50 substrates for getting higher through-put. In another embodiment, the frequency of cleaning may be reduced to every 2 to 50 substrates including 2 substrates, 4 substrates, one lot (25 substrates), and two lots (50 substrates), preferably every 4 substrates.

In another embodiment, a cleaning gas may further comprise a plasma stabilizing gas such as one or more of inert gas (e.g., He, Ne, Ar), N₂, and CO₂, so that an etchant (etching agent) can reach every corner of the reactor. The plasma stabilizing gas may be added in an amount of about 1% to less than 50% (preferably less than 30%) of the total cleaning gas.

By manipulating the above control parameters for cleaning, it becomes possible to differently control a cleaning rate at the electrodes and a cleaning rate on an inner wall of the reactor without generating contaminant particles. For example, a ratio of a cleaning rate at an inner wall of the reactor to a cleaning rate at an upper electrode can be adjusted in the range of 3/100 to 110/100 (including 5/100, 10/100, 30/100, 50/100, 70/100, 100/100, and ranges between any two numbers of the foregoing). In an embodiment, the etching rate on an inner wall of the reactor may be adjusted in the range of about 40 nm/min to about 2,000 nm/min (50 nm/min, 100 nm/min, 200 nm/min, 500 nm/min, 1,000 nm/min, 1,500 nm/min, and ranges between any two numbers of the foregoing), and the etching rate at an electrode of the reactor may be adjusted in the range of about 300 nm/min to about 2,500 nm/min (400 nm/min, 600 nm/min, 1,000 nm/min, 1,500 nm/min, 2,000 nm/min, and ranges between any two numbers of the foregoing).

In an embodiment, two-step cleaning may be performed. In the 1^{st} step, by using a high oxygen gas flow rate such as 5,000 sccm to 10,000 sccm, a high RF power such as 2,500 W to 3,000 W, a high pressure such as 400 Pa to 800 Pa, and a small gap between the electrodes such as 15 mm to 35 mm, a high cleaning rate such as 2,000 nm/min to 4,000 nm/min (especially 3,000 nm/min or higher in a center area of the electrode) can be achieved. The 1^{st} step may not be effective to clean an inner wall of the chamber. This 1^{st} step may further be divided into two steps to increase cleaning efficiency. In order to clean the inner wall, the 2^{nd} step may be performed by using a lower oxygen gas flow rate such as 2,000 sccm to 4,500 sccm (with 3-9% of F-containing gas), a lower pressure such as 100 Pa to 300 Pa, and a greater gap between the electrodes such as 35 mm to 65 mm, a high cleaning rate such as 600 nm/min to 1,000 nm/min for the inner wall can be achieved. This 2^{nd} step may further be divided into two steps to increase cleaning efficiency.

In the present disclosure where conditions and/or structures are not specified, the skilled artisan in the art can readily provide such conditions and/or structures, in view of the present disclosure, as a matter of routine experimentation.

### EXAMPLES

The present invention will be explained with reference to preferred embodiment and drawings. The preferred embodiments and drawings are not intended to limit the present invention.

Nano-Carbon Polymer Formation

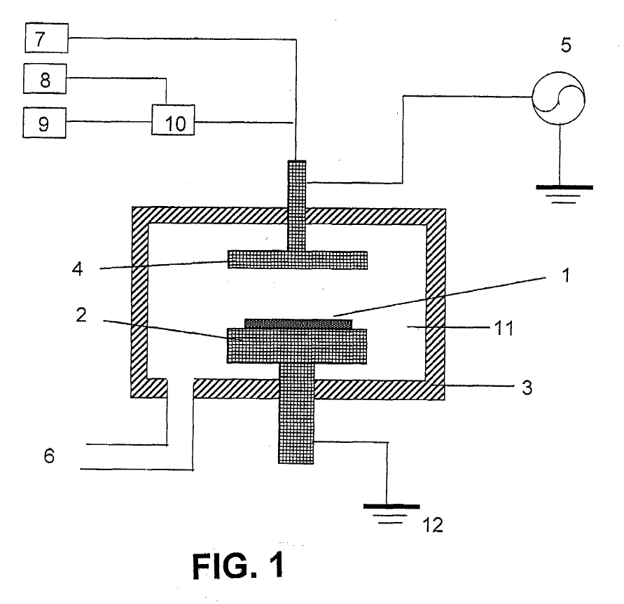

FIG. 1 is a schematic view of an apparatus combining a vaporizer and a plasma CVD reactor, which can be used in the present invention. An apparatus which can be used in the present invention is not limited to an example shown in FIG. 1.

In this example, by providing a pair of electrically conductive flat-plate electrodes 4, 2 in parallel and facing each other inside a reaction chamber 11, applying RF power 5 to one side, and electrically grounding 12 the other side, plasma is excited between the electrodes. A temperature regulator is provided in a lower stage 2, and a temperature is kept constantly at a given temperature in the range of 0° C.-650° C. to regulate a temperature of a substrate 1 placed thereon. An upper electrode 4 serves as a shower plate as well, and reaction gas is introduced into the reaction chamber 11 through the shower plate. Additionally, in the reaction chamber 11, an exhaust pipe 6 is provided through which gas inside the reaction chamber 11 is exhausted.

A vaporizer 10 which vaporizes a liquid organic monomer has an inlet port for a liquid and an inlet port for an inert gas in an embodiment and comprises a mixing unit for mixing these gases and a unit for heating the mixture. In the embodiment shown in FIG. 1, an inert gas is introduced from an inert gas flow-controller 8 to the vaporizer 10; and a liquid monomer is introduced from a liquid monomer flow-controller 9 into the vaporizer 10. A heating temperature of the liquid monomer flow-controller 9 and the liquid source piping between the liquid monomer flow-controller 9 and the vaporizer 10 is determined based on characteristics of a liquid source; the temperature is kept in the range of 0° C.-150° C. in this embodiment. A heating temperature of a vaporizer 10 is also determined based on characteristics of a liquid source; the temperature is kept in the range of 0° C.-150° C. in this embodiment. In an embodiment, the liquid monomer includes a polymeric liquid. In that case, the temperature should be kept low. Vaporized gas is introduced into the reactor through gas piping. Additionally, the embodiment shown in FIG. 1 is designed to be able to introduce an additive gas from a gas flow-controller 7 into the reactor. Additionally, an inert gas can also be introduced into the reactor without passing through the vaporizer 10. The number of the gas flow-controller 7 is not limited to one, but can be provided appropriately to meet the number of gas types used.

The piping introducing the gas from the vaporizer to the reactor and a showerhead unit in an upper portion of the reactor are heated/temperature-controlled at a given temperature in the range of 30° C.-350° C. by a heater and their outer side is covered by an insulating material.

Deposition conditions: Deposition conditions in the examples are as follows: Eagle®12 (ASM Japan) possessing a basic structure shown in FIG. 1 was used as a reactor. Additionally, in the case of these examples, although a liquid monomer was flow-controlled by a flow control unit in a liquid phase, an amount of gas introduced into a reactor was obtained by molar conversion from the flow rate of the liquid.

Reactor Settings:

Temperature of upper electrode (shower plate): 180° C.

Temperature of inner wall: 180° C.

Size of shower plate: φ350 mm

(Size of substrate: φ300 mm)

Susceptor temperature: 400° C.

Controlled temperature of gas inlet piping: 140° C.

Gap between shower plate and susceptor: 16 mm

Process Conditions:

TMB (1,3,5-trimethylbenzene): 1.65 g/min

He supplied to vaporizer: 400 sccm

Process gas He supplied to reactor: 30 sccm

RF Power (13.56 MHz): 1150 W

RF Power (430 kHz): 300 W

Pressure: 800 Pa

After depositing a nano-carbon polymer film on a semiconductor substrate, cleaning began under respective conditions described blow.

### Example 1

As a cleaning gas, O₂ gas was solely used. Cleaning conditions in this example and cleaning results are shown as follows. A cleaning rate (etching rate) was evaluated at a center of the upper electrode (showerhead) and an inner wall facing a gate valve.

Cleaning Conditions:

Gap between shower plate and susceptor: 25 mm

O₂ gas: 3,000 sccm

RF Power (13.56 MHz): 1800 W

Pressure: 150 Pa

Cleaning time: 15 sec

Cleaning Rates:

Electrode: 460 nm/min

Wall: 320 nm/min

### Example 2

Under the same conditions as in Example 1 except for the pressure which was controlled at 533 Pa. A cleaning rate (etching rate) was evaluated at a center of the upper electrode (showerhead) and an inner wall facing a gate valve.

Cleaning Rates:

Electrode: 1150 nm/min

Wall: 50 nm/min

As shown above, by increasing the cleaning pressure from 150 Pa to 533 Pa, the cleaning rate at the electrode increased from 460 nm/min to 1150 nm/min which is 2.5-fold. On the other hand, the cleaning rate on the inner wall decreased from 320 nm/min to 50 nm/min which is less than 1/6-fold. By using O₂ gas as the cleaning gas, the ratio of a cleaning rate at the electrode to a cleaning rate on the inner wall can highly be manipulated by changing the pressure. In the above examples, the ratio was changed from 2.5 to 1/6.

### Example 3

As a cleaning gas, N₂O gas was solely used. Cleaning conditions in this example and cleaning results are shown as follows. A cleaning rate (etching rate) was evaluated at a center of the upper electrode (showerhead) and an inner wall facing a gate valve.

Cleaning Conditions:

Gap between shower plate and susceptor: 25 mm

N₂O gas: 3,000 sccm

RF Power (13.56 MHz): 1800 W

Pressure: 150 Pa

Cleaning time: 15 sec

Cleaning Rates:

Electrode: 1770 nm/min

Wall: 1580 nm/min

### Example 4

Under the same conditions as in Example 3 except for the pressure which was controlled at 533 Pa. A cleaning rate (etching rate) was evaluated at a center of the upper electrode (showerhead) and an inner wall facing a gate valve.

Cleaning Rates:

Electrode: 2220 nm/min

Wall: 1210 nm/min

As shown above, by increasing the cleaning pressure from 150 Pa to 533 Pa, the cleaning rate at the electrode increased from 1770 nm/min to 2220 nm/min which is 1.25-fold. On the other hand, the cleaning rate on the inner wall decreased from 1580 nm/min to 1210 nm/min which is about 3/4-fold. By using N₂O gas as the cleaning gas, the ratio of a cleaning rate at the electrode to a cleaning rate on the inner wall can be manipulated by changing the pressure. In the above examples, the ratio was changed from 1.25 to 3/4. The change of the ratio was not as good as in Examples 1 and 2; however, the cleaning rate on the inner wall by using N₂O gas at 150 Pa was about 5 times greater than that by using O₂ gas, and furthermore, the cleaning rate on the inner wall by using N₂O gas at 533 Pa was about 24 times greater than that by using O₂ gas. It can be understood that O₂ gas and high pressure are useful to selectively cleaning the electrode, and N₂O gas and low pressure are useful to cleaning the inner wall.

### Example 5

As a cleaning gas, C₃F₈ gas was added to O₂ gas. Cleaning conditions in this example and cleaning results are shown as follows. A cleaning rate (etching rate) was evaluated at a center of the upper electrode (Chamber center), an inner wall in the vicinity of an exhaust outlet (Chamber wall 1), and an inner wall facing a gate valve (Chamber wall 2)

Cleaning Conditions:

Gap between shower plate and susceptor: 25 mm

O₂ gas: 3,000 sccm

C₃F₈ gas: 30 sccm

RF Power (13.56 MHz): 1800 W

Pressure: 150 Pa

Cleaning time: 15 sec

Cleaning Rates:

Chamber center: 741 nm/min

Chamber wall 1: 498 nm/min

Chamber wall 2: 771 nm/min

As shown above, by adding about 1% C₃F₈ gas to O₂ gas, as compared with Example 1, the cleaning rate at the electrode increased from 460 nm/min to 741 nm/min which is 1.6-fold. The cleaning rate on the inner wall (facing the gave valve) increased from 320 nm/min to 771 nm/min which is about 2.4-fold. In Example 1, the cleaning rate on the inner wall in the vicinity of the exhaust outlet was 118 nm/min. Thus, the cleaning rate on the inner wall (in the vicinity of the exhaust outlet) increased from 118 nm/min to 498 nm/min which is about 4.2-fold. By adding C₃F₈ gas, the ratio of a cleaning rates especially on the inner wall increased. However, as shown in Example 6 described below, contaminant particles were increasingly accumulated on substrates as deposition and cleaning were repeated.

### Example 6

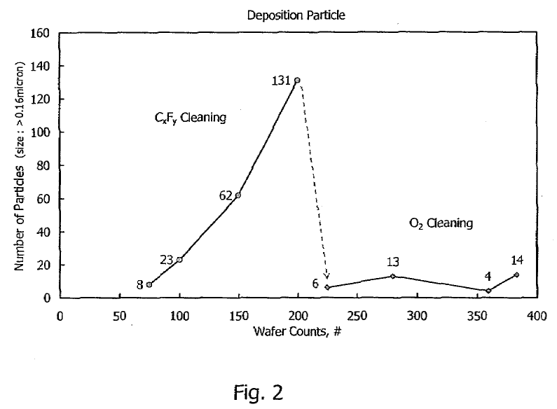

Deposition of a nano-carbon polymer film on a substrate and cleaning of the reactor were repeated, and the number of particles having a particle size of 0.16 μm or greater on the substrates was measured every after deposition of a nano-carbon polymer film on a substrate. From a first substrate to a 200th substrate, the cleaning conditions applied after each deposition were the same as in Example 5, and from a 201st substrate, the cleaning conditions applied after each deposition were the same as in Example 1. The results are shown in FIG. 2.

As shown in FIG. 2, when C₃F₈ gas was added, the number of particles increased constantly as the number of substrates processed increased. However, after changing the gas to O₂ gas without C₃F₈ gas, the number of particles drastically fell and thereafter remained low.

### Example 7

In this example, oxygen gas flow and RF power were both increased, thereby increasing the cleaning rate. Further, the cleaning was conducted in two steps (in another embodiment, the cleaning may be conducted in three or more steps, or each of the two steps may be conducted in two or more steps).

Deposition conditions: Deposition conditions in the example are as follows: Eagle® (ASM Japan) possessing a basic structure shown in FIG. 1 was used as a reactor. Additionally, although a liquid monomer was flow-controlled by a flow control unit in a liquid phase, an amount of gas introduced into a reactor was obtained by molar conversion from the flow rate of the liquid.

Reactor Settings:

Temperature of upper electrode (shower plate): 120° C.

Temperature of inner wall: 120° C.

Size of shower plate: φ350 mm

(Size of substrate: φ300 mm)

Susceptor temperature: 300° C.

Controlled temperature of gas inlet piping: 140° C.

Gap between shower plate and susceptor: 16 mm

Process Conditions:

C₅H₈: 0.4 g/min

He supplied to vaporizer: 500 sccm

Process gas He supplied to reactor: 1,000 sccm

RF Power (13.56 MHz): 2,000 W

RF Power (430 kHz): 0 W

Pressure: 600 Pa

After depositing a nano-carbon polymer film on a semiconductor substrate, cleaning began under respective conditions described blow.

Cleaning conditions in this example and cleaning results are shown as follows. A cleaning rate (etching rate) was evaluated at a center area and a periphery area of the upper electrode (showerhead) and an inner wall facing a gate valve. In this example, the 2^{nd} cleaning step was conducted at a lower pressure to clean the inner wall of the chamber. Further, as a cleaning gas for the 2^{nd} step, C₃F₈ gas was added to O₂ gas.

Cleaning Conditions (Two-Step Cleaning):

<1^{st} Step (Higher Pressure Cleaning)>

Gap between shower plate and susceptor: 25 mm

O₂ gas: 7,000 sccm

RF Power (13.56 MHz): 2,700 W

Pressure: 600 Pa

Cleaning time: 30 sec

Cleaning Rates:

Electrode center area: 3,500 nm/min

Electrode outer area: 2,500 nm/min

<2^{nd} Step (Lower Pressure Cleaning)>

Gap between shower plate and susceptor: 50 mm

O₂/C₃F₈ gas: 3,500/200 sccm

RF Power (13.56 MHz): 2,700 W

Pressure: 200 Pa

Cleaning time: 20 sec

Cleaning Rates:

Inner wall area: 800 nm/min

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method of continuously forming carbon-based films on substrate, comprising:
(i) forming a carbon-based film on a substrate in a reactor a pre-selected number of times;
(ii) exciting oxygen gas and/or nitrogen oxide gas to generate a plasma for cleaning;
(iii) cleaning an inside of the reactor with the plasma to remove particles accumulated during step (i) on the inside of the reactor; and
(iv) repeating steps (i)-(iii) a pre-selected number of times.

2. The method according to claim 1, wherein step (ii) is conducted in the reactor.

3. The method according to claim 2, further comprising determining a priority area of cleaning inside the reactor prior to step (ii).

4. The method according to claim 3, wherein step (iii) comprises controlling pressure inside the reactor according to the priority area of cleaning.

5. The method according to claim 4, wherein step (iii) comprises controlling pressure inside the reactor at about 100 Pa to about 400 Pa when the priority area of cleaning is an inner wall of the reactor.

6. The method according to claim 4, wherein step (iii) comprises controlling pressure inside the reactor at about 400 Pa to about 800 Pa when the priority area of cleaning is an upper electrode.

7. The method according to claim 2, wherein step (iii) comprises controlling a gap between an upper electrode and a lower electrode according to the priority area of cleaning.

8. The method according to claim 3, further comprising selecting a cleaning gas including the oxygen gas and/or nitrogen oxide gas prior to step (ii) according to the priority area of cleaning.

9. The method according to claim 3, wherein step (iii) comprises a step for adjusting a ratio of a cleaning rate at an inner wall of the reactor to a cleaning rate at an upper electrode to 3/100 to 110/100 according to the priority area of cleaning.

10. The method according to claim 9, wherein step (iii) comprises a 1^{st} step of targeting the upper electrode as the priority area and a 2^{nd} step of targeting the inner wall as the priority area, wherein the 1^{st} step controls an oxygen gas flow rate in the range of 5,000 sccm to 10,000 sccm, an RF power in the range of 2,500 W to 3,000 W, a pressure in the range of 400 Pa to 800 Pa, and a gap between the electrodes in the range of 15 mm to 35 mm, and the 2^{nd} step controls an oxygen gas flow rate in the ranged of 2,000 sccm to 4,500 sccm, a pressure in the range of 100 Pa to 300 Pa, and a gap between the electrodes in the range of 35 mm to 65 mm.

11. The method according to claim 10, wherein in the 1^{st} step, the oxygen gas is the only cleaning gas, and in the 2^{nd} step, 3-9% of F-containing gas is added to the oxygen gas.

12. The method according to claim 2, wherein step (ii) further comprises exciting a fluorine-containing gas, a flow rate of which is lower than that of the oxygen gas and/or nitrogen oxide gas, when the priority area of cleaning is an inner wall.

13. The method according to claim 2, wherein step (ii) further comprises exciting an inert gas, N₂ gas, and/or CO₂ gas, a total flow rate of which is lower than that of the oxygen gas and/or nitrogen oxide gas, when the priority area of cleaning is an inner wall.

14. The method according to claim 2, wherein step (ii) comprises exciting predominantly the nitrogen oxide gas when the priority area of cleaning is an inner wall.

15. The method according to claim 2, wherein step (ii) comprises exciting predominantly the oxygen gas without a fluorine-containing gas when the priority area of cleaning is an upper electrode.

16. The method according to claim 1, wherein in step (i), the oxygen gas and/or nitrogen oxide gas is O₂ gas and/or N₂O gas.

17. The method according to claim 12, wherein the nitrogen oxide gas is N₂O.

18. The method according to claim 13, wherein the oxygen gas is O₂ gas.

19. The method according to claim 2, wherein step (ii) is conducted in the reactor and in a remote plasma unit.

20. The method according to claim 1, wherein the carbon-based polymer film in step (i) is a carbon polymer film formed by:
vaporizing a hydrocarbon-containing liquid monomer (C_{α}H_{βX}_{γ}, wherein α and β are natural numbers of 5 or more; γ is an integer including zero; X is O, N or F) having a boiling point of about 20° C. to about 350° C. which is not substituted by a vinyl group or an acetylene group;
introducing said vaporized gas into a CVD reaction chamber inside which a substrate is placed; and
forming a hydrocarbon-containing polymer film on said substrate by plasma polymerization of said gas.

21. A method of self-cleaning a plasma reactor using a cleaning gas containing oxygen gas and/or nitrogen oxide gas at a pre-selected pressure upon depositing a carbon-based film on a substrate a pre-selected number of times, comprising:
(i) changing the cleaning gas and/or the pressure,
the step of changing the cleaning gas comprising (a) increasing a flow rate of oxygen gas for increasing a ratio of an etching rate of a carbon polymer accumulated on an upper electrode provided in the reactor to an etching rate of a carbon polymer accumulated on an inner wall of the reactor, or (b) increasing a flow rate of nitrogen oxide gas and/or adding to the cleaning gas at least one gas selected from the group consisting of fluorine-containing gas, inert gas, N₂ gas, and CO₂ gas for decreasing a ratio of an etching rate of the carbon polymer on the upper electrode to an etching rate of the carbon polymer on the inner wall,
the step of changing the pressure comprising (c) increasing the pressure for increasing a ratio of an etching rate of the carbon-based film on the upper electrode to an etching rate of the carbon-based film on the inner wall, or (d) decreasing the pressure for decreasing a ratio of an etching rate of the carbon-based film on the upper electrode to an etching rate of the carbon-based film on the inner wall; and
(ii) conducting self-cleaning of the reactor using the changed cleaning gas and/or the changed pressure.

22. The method according to claim 21, wherein step (c) comprises adjusting the pressure at about 100 Pa to about 400 Pa.

23. The method according to claim 21, wherein step (d) comprises adjusting the pressure at about 400 Pa to about 800 Pa.

24. The method according to claim 21, wherein in step (i), the oxygen gas is O₂ gas, and the nitrogen oxide gas is N₂O gas.

25. The method according to claim 21, wherein the carbon-based film in step (i) is a carbon polymer film formed by:
vaporizing a hydrocarbon-containing liquid monomer (C_{α}H_{β}H_{γ}, wherein α and β are natural numbers of 5 or more; γ is an integer including zero; X is O, N or F) having a boiling point of about 20° C. to about 350° C. which is not substituted by a vinyl group or an acetylene group;
introducing said vaporized gas into a CVD reaction chamber inside which a substrate is placed; and
forming a hydrocarbon-containing polymer film on said substrate by plasma polymerization of said gas.

26. A method of self-cleaning a plasma reactor upon depositing a carbon-based film on a substrate a pre-selected number of times, comprising:
(i) exciting oxygen gas and/or nitrogen oxide gas to generate a plasma; and
(ii) exposing to the plasma a carbon-based film accumulated on an upper electrode provided in the reactor and a carbon-based film accumulated on an inner wall of the reactor.

27. The method according to claim 26, wherein step (i) is conducted in the reactor.

28. The method according to claim 27, wherein step (ii) is conducted at a pressure of about 100 Pa to about 800 Pa.

29. The method according to claim 27, wherein in step (i), the plasma is generated only from oxygen gas.

30. The method according to claim 27, wherein in step (i), the plasma is generated only from nitrogen oxide gas.

31. The method according to claim 29, wherein step (i) further comprises exciting at least one gas selected from the group consisting of fluorine-containing gas, inert gas, N₂ gas, and CO₂ gas.

32. The method according to claim 26, further comprising adjusting a gap between an upper electrode and a lower electrode provided in the reactor.

33. The method according to claim 26, wherein in step (i), the oxygen gas and/or nitrogen oxide gas is O₂ gas and/or N₂O gas.

34. The method according to claim 26, wherein the carbon-based film in step (i) is a carbon polymer film formed by:
vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which is not substituted by a vinyl group or an acetylene group;
introducing said vaporized gas into a CVD reaction chamber inside which a substrate is placed; and
forming a hydrocarbon-containing polymer film on said substrate by plasma polymerization of said gas.
